(19) United States
(12) Patent Application Publication
(10) Pub. No.: US 2024/0185926 A1
(43) Pub. Date: Jun. 6, 2024

(54) WRITING USER DATA INTO STORAGE MEMORY

(71) Applicant: Micron Technology, Inc., Boise, ID (US)

(72) Inventors: Huai-Yuan Tseng, San Ramon, CA (US); Kishore Kumar Mucherla, San Jose, CA (US); William Charles Filipiak, Northville, MI (US); Eric N. Lee, San Jose, CA (US); Andrew Bicksler, Nampa, ID (US); Ugo Russo, Boise, ID (US); Niccolo' Righetti, Boise, ID (US); Christian Caillat, Boise, ID (US); Akira Goda, Setagaya (JP); Ting Luo, Santa Clara, CA (US); Antonino Pollio, Vico Equense (IT)

(21) Appl. No.: 18/517,903

(22) Filed: Nov. 22, 2023

Related U.S. Application Data
(60) Provisional application No. 63/429,362, filed on Dec. 1, 2022.

(51) Int. Cl. G11C 16/10; G11C 16/16; G11C 16/34

(52) U.S. Cl. CPC G11C 16/102; G11C 16/16; G11C 16/3404

(57) ABSTRACT

A variety of applications can include one or more memory devices having user data preloaded for the application prior to reflowing the memory devices on the system platform of the application. A touch-up data refresh method can be implemented to gain read window budget and to improve retention slope to protect the preload content to tolerate reflow to the system platform. Techniques for data preload can include programming preload data into targeted blocks until the targeted blocks are programmed with the preload data and re-programming the preload data over the programmed preload data in the targeted blocks in a same set of memory cells, without an erase between programming and re-programming the preload data. Variations of such techniques can be used to prepare a memory device with preload data followed by performing a reflow of the memory device to a structure for an application to which the memory device is implemented.

### PRIORITY APPLICATION

This application claims the benefit of priority to U.S. Provisional Application Ser. No. 63/429,362, filed 1 Dec. 2022, which is incorporated herein by reference in its entirety.

### FIELD OF THE DISCLOSURE

Embodiments of the disclosure relate generally to electronic devices and, more specifically, to storage memory devices and operation thereof.

### BACKGROUND

Memory devices are typically provided as internal, semiconductor, integrated circuits in computers or other electronic devices in a variety of manufactured products. There are many different types of memory, including volatile and non-volatile memory. Volatile memory requires power to maintain its data, and examples of volatile memory include random-access memory (RAM), dynamic random-access memory (DRAM), static RAM (SRAM), and synchronous dynamic random-access memory (SDRAM), among others. Non-volatile memory can retain stored data when not powered, and examples of non-volatile memory include flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), and three-dimensional (3D) XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a data line.

The various types of memory devices can be used in applications in which manufacturers of consumer products prefer to have the memory devices preloaded with content prior to being attached to the system board for the application for which the memory device is to be implemented. For example, automotive manufacturers, who are customers to the integrated circuit device industry, prefer to preload content such as navigation maps and other to memory devices before the memory devices are soldered to their system boards. Operation and properties of memory devices and other electronic devices in systems can be improved by enhancements to the procedures and design of these electronic devices for their introduction into the systems for which the electronic devices are intended.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates representive plots of read window budget for three procedures using an infrared reflow analyzed with respect to retention in the field for a specification of approximately one year at 55° ° C., according to various embodiments.

FIG. 2 illustrates an example of an environment including a host device and a memory device configured to communicate over a communication interface, according to various embodiments.

FIG. 3 is a flow diagram of an example method of preparing a memory device with preload data followed by performing a reflow of the memory device to a structure for an application to which the memory device is implemented, according to various embodiments.

FIG. 4 is a flow diagram of another example method of preparing a memory device with preload data followed by performing a reflow of the memory device to a structure for an application to which the memory device is implemented, according to various embodiments.

FIG. 5 is a flow diagram of another example method of preparing a memory device with preload data followed by performing a reflow of the memory device to a structure for an application to which the memory device is implemented, according to various embodiments.

FIG. 6 illustrates an example block diagram of a memory device including a memory array having a plurality of memory cells, and one or more circuits or components to provide communication with or perform one or more memory operations on the memory array, according to various embodiments.

FIG. 7 is a block diagram of an example system including a host that operates with a memory system having one or more memory devices having preload data for the application for which the memory system is implemented, according to various embodiments.

FIG. 8 is a block diagram illustrating an example of a machine upon which one or more embodiments may be implemented, according to various embodiments.

### DETAILED DESCRIPTION

The following detailed description refers to the accompanying drawings that show, by way of illustration and not limitation, various embodiments in which an invention can be practiced. These embodiments are described in sufficient detail to enable those skilled in the art to practice these and other embodiments. Other embodiments may be utilized, and structural, logical, mechanical, and electrical changes may be made to these embodiments. The various embodiments are not necessarily mutually exclusive, as some embodiments can be combined with one or more other embodiments to form new embodiments. The following detailed description is, therefore, not to be taken in a limiting sense.

Both NOR and NAND flash architecture semiconductor memory arrays of flash memory devices are accessed through decoders that activate specific memory cells by selecting an access line (WL) coupled to gates of specific memory cells. In a NOR architecture semiconductor memory array, once activated, the selected memory cells place their data values on data lines, causing different currents to flow depending on the state at which a particular cell is programmed. In a NAND architecture semiconductor memory array, a relatively high bias voltage is applied to a drain-side select gate (SGD) line. Access lines coupled to the gates of the unselected memory cells of each group are driven at a specified pass voltage (Vpass) to operate the unselected memory cells of each group as pass transistors (e.g., to pass current in a manner unrestricted by their stored data values). Current then flows in the line between the source line and the data line through each series-coupled group, restricted only by the selected memory cells of each group, placing current-encoded data values of selected memory cells on the data lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC has been referred to as a memory cell that can store two bits of data per cell (e.g., one of four programmed states). MLC is used herein, in its broader context, to refer to any memory cell(s) that can store more than one bit of data per cell (i.e., that can represent more than two programmed states). Herein, a memory cell that can store two bits of data per cell (e.g., one of four programmed states) is referred to as a dual-level cell (DLC). A triple-level cell (TLC) refers to a memory cell that can store three bits of data per cell (e.g., one of eight programmed states). A quad-level cell (QLC) can store four bits of data per cell, and a penta-level cell (PLC) can store 5 bits of data per cell. Each programmed state can be associated with its own threshold voltage, V_{T}. For example, in a TLC that has eight programmed states, there are eight separate threshold voltages. The separation in voltage between adjacent VTs defines a margin for reliability of the memory cells. As the voltage different between distributions of memory cells for adjacent V_{T}s narrows, the margin decreases with the increased probability of the overlap of distribution of different programmed states.

Some consumer product manufacturers, such as automotive customers, prefer to preload data to memory devices, such as memory devices of managed memory systems, before reflow of the memory devices to their system board. Preload data is data content that is user data of a product manufacturer for operation of applications of the respective consumer product. Reflow of an integrated circuit (IC) device, such as a packaged memory device, is the process of attaching, typically by soldering, the IC device to a system board. In a memory system structured as a managed memory system, memory devices with preload data can be soldered to a system board for the managed memory system. The managed memory system can be, but is not limited to, a managed NAND memory system. In general, a managed NAND memory system, also referred to as managed NAND (mNAND), is realized as a combination of one or more individual NAND flash memory devices combined with a hardware controller that performs management features for the flash memories. Solid-state drive (SSD), Universal Flash Storage (UFS™), and embedded MultiMediaCard (eMMC™) devices can be included in managed NAND memory systems that also can include processing circuitry such as one or more of memory processing devices, direct memory access (DMA) controllers, and flash memory interface circuitry to manage the access to physical memory.

Memory devices, such as but not limited to mNAND devices, can be reflowed by an infrared (IR) reflow. An IR reflow of a memory device can subject the memory device to a high temperature of approximately 260° C. This high temperature procedure generates a temperature stress to the memory cells of the memory device, where the temperature stress degrades the reliability margin of the preloaded data in the memory cells of the memory device. In a NAND memory device, as an example, the temperature stress can cause a shift of the voltage threshold of one or more memory cells to a lower voltage threshold value. As a result, NAND data retention capability is reduced, and the bit error rate of the memory device becomes higher in operation in the field of the consumer product. Data retention, which is the storing of information for a specified period, refers to the ability of a memory cell to retain its data state over long periods of time without regard to power status (on or off).

Typically, in conventional approaches, after preload data is input to a memory device and an IR reflow is performed, a read window budget (RWB) and retention in the field of the memory device can be insufficient to meet desired specifications. A RWB can refer to the cumulative value in voltage of a number of distances in voltage between adjacent V_{T} distributions at a particular bit error rate (BER). There are a number of conventional approaches to generate gain in RWB margin. With respect to a standard time to program (tPROG), a slow trim with a program time increased to twice tPROG can be used to program the preload data, which raises the RWB. However, the use of the slow trim can degrade the throughput of the factory installing the memory device on a system board of a product. Another conventional approach is to perform a data refresh after IR reflow, where a data refresh is a copy operation to new blocks. The data refresh can be implemented to improve RWB margin. However, the data refresh in a memory device after reflow can degrade factory throughput, for example for some applications by appropriately 30 minutes per memory device.

In various embodiments, a touch-up data refresh method can be implemented to gain a RWB and to improve retention slope to protect the preload content of a memory device prior to subjecting the memory device to reflow. Such a touch-up can allow the memory device to sustain reflow, such as an IR reflow, for consumer product applications, for example but not limited to automotive applications, and to pass the reliability specifications. The touch-up data refresh procedure can resolve the RWB shortage to tolerate IR reflow and achieve reliability in the field. The touch-up data refresh procedure can improve retention margin after reflow without using data refresh after reflow. The touch-up data refresh procedure can provide faster throughput than the existing conventional method of slowing down write performance to gain RWB margin. Retention slope can be improved after touch-up data refresh.

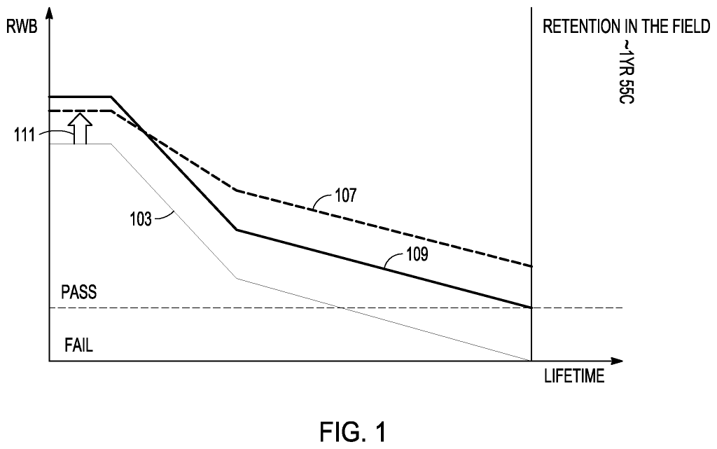

FIG. 1 illustrates representive plots of RWB for three procedures using a IR reflow analyzed with respect to retention in the field for a specification of approximately one year at 55° C. Plot 103 is for a conventional trim and plot 109 is a conventional slow trim. Plot 107 is for a trim slowed from the procedure of plot 103 by an amount 111 and then subjected to touch-up to refresh the data before the IR reflow. The procedure of plot 103 enters a fail region before the procedure of plot 109, which enters the fail region at the approximate one year point, while the procedure of plot 107 remains in the pass region at the one year mark. The procedure of plot 107 is an embodiment of an in-place touch-up to refresh the data before IR reflow to gain RWB margin and to improve retention slope, which results in the plot 107 being significantly above the pass-fail level at the one year point. The improved retention slope occurs due to the touch-up filling trap positions, which become vacant due to de-trapping. The touch-up procedure of plot 107 allows the avoidance of a data refresh after IR reflow. This avoidance can provide a time savings in the manufacturing process for a memory device to a system board. In some applications, there can be a savings of approximately 30 minutes per memory device. With respect to the touch-up process, the RWB at the end of life (EOL) can have a value of a conventional process plus the RWB attributed to the touch-up, which can be much greater than the RWB of the conventional process. With respect to the tPROG, the conventional trim time plus the time associated with touch-up can be significantly less than the time for a slower trim plus the time for data refresh after reflow (for example, in some applications thirty minutes per memory device). Touch-up program time can be slightly less than conventional trim, such that the conventional trim plus touch-up is slightly less than twice tPROG.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile random-access memory (RAM) memory device, such as dynamic RAM (DRAM), mobile or low-power double-data-rate synchronous DRAM (DDR SDRAM), etc.); and a storage device (e.g., non-volatile memory (NVM) device, such as flash memory, ROM, an SSD, an MMC, or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. The memory devices can be preloaded with user data for various applications of electronic devices using the touch-up process discussed with respect to FIG. 1 or other preload procedure that is conducted prior to subjecting the memory devices to reflow, which can optionally eliminate use of a data refresh after reflow.

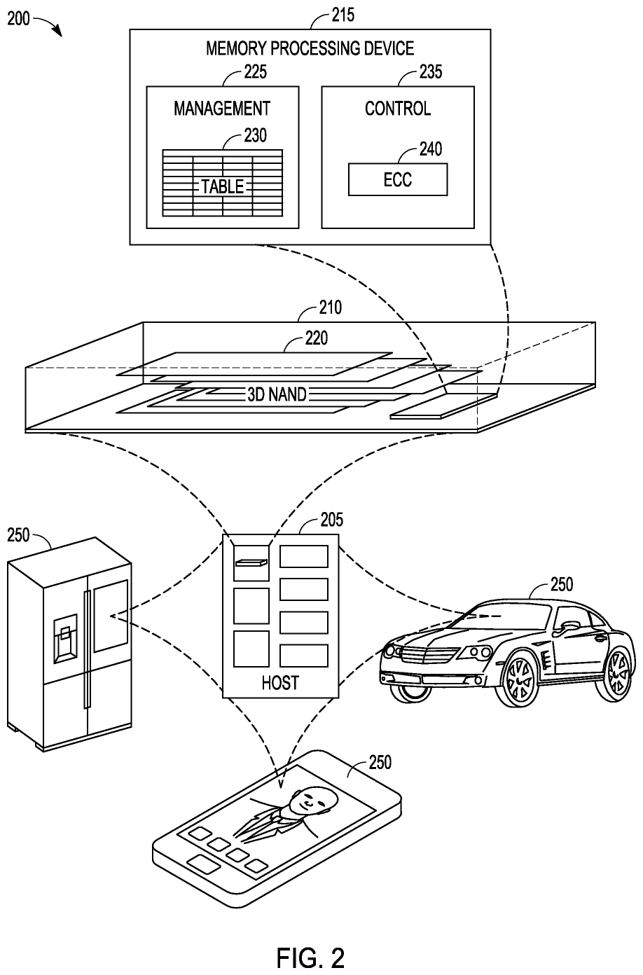

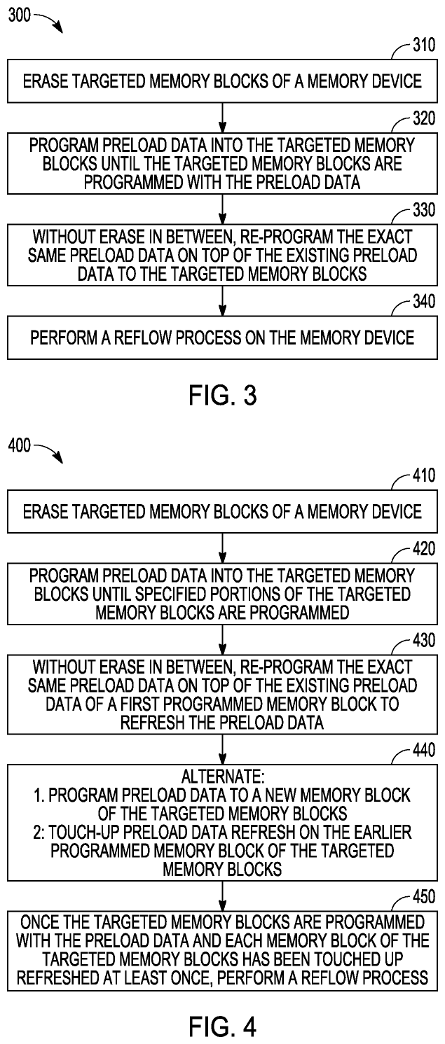

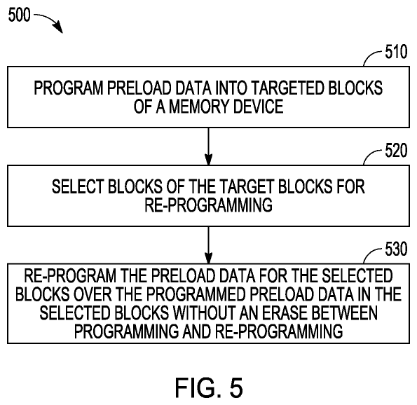

FIG. 2 illustrates an example of an environment 200 including a host device 205 and a memory device 210 configured to communicate over a communication interface, where memory device 210 can contain preload data. The preload data can be loaded according to procedures for preparing a memory device with preload data followed by performing a reflow of the memory device to a structure for an application to which the memory device is implemented, as taught herein. Examples of embodiments to program preload data prior to reflow include, but are not limited to, methods associated with plot 107 of FIG. 1, method 300 of FIG. 3, method 400 of FIG. 4, and method 500 of FIG. 5. Memory device 210 can be included in a variety of products 250, such as Internet of Things (IOT) devices (e.g., a refrigerator or other appliance, sensor, motor or actuator, mobile communication device, automobile, drone, etc.) to support processing, communications, or control of products 250. Host device 205 can also be included in the variety of products 250.

Memory device 210 includes a memory processing device 215 and a memory array 220 including, for example, a number of individual memory die (e.g., a stack of three-dimensional (3D) NAND die). In 3D architecture semiconductor memory technology, vertical structures are stacked, increasing the number of tiers, physical pages, and accordingly, the density of a memory device (e.g., a storage device). In an example, memory device 210 can be a discrete memory or storage device component of host device 205. In other examples, memory device 210 can be a portion of an integrated circuit (e.g., system on a chip (SOC), etc.), stacked or otherwise included with one or more other components of host device 205.

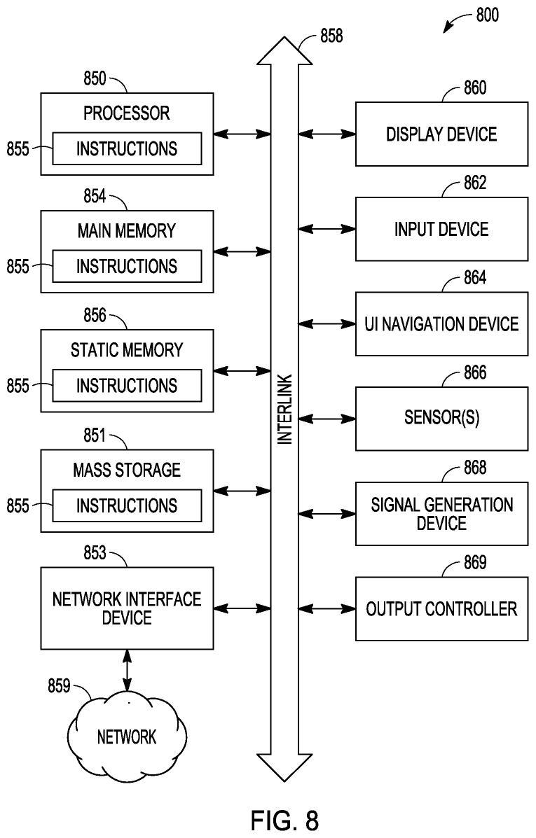

One or more communication interfaces can be used to transfer data between memory device 210 and one or more other components of host device 205, such as a Serial Advanced Technology Attachment (SATA) interface, a Peripheral Component Interconnect Express (PCIe) interface, a Universal Serial Bus (USB) interface, a UFS interface, an eMMC™ interface, or one or more other connectors or interfaces. Host device 205 can include a host system, an electronic device, a processor, a memory card reader, or one or more other electronic devices external to memory device 210. In some examples, host device 205 may be a machine having some portion, or all, of the components discussed in reference to the machine 800 of FIG. 8.

Memory processing device 215 can receive instructions from host device 205, and can communicate with memory array 220, such as to transfer data to (e.g., write or erase) or from (e.g., read) one or more of the memory cells, planes, sub-blocks, blocks, or pages of memory array 220. Memory processing device 215 can include, among other things, circuitry or firmware, including one or more components or integrated circuits. For example, memory processing device 215 can include one or more memory control units, circuits, or components configured to control access across memory array 220 and to provide a translation layer between host device 205 and memory device 210. Memory processing device 215 can include one or more input/output (I/O) circuits, lines, or interfaces to transfer data to or from memory array 220. Memory processing device 215 can include a memory manager 225 and an array controller 235.

Memory manager 225 can include, among other things, circuitry or firmware, such as a number of components or integrated circuits associated with various memory management functions. For purposes of the present description, example memory operation and management functions will be described in the context of NAND memory. Persons skilled in the art will recognize that other forms of non-volatile memory may have analogous memory operations or management functions. Such NAND management functions include wear leveling (e.g., garbage collection or reclamation), error detection or correction, block retirement, or one or more other memory management functions. Memory manager 225 can parse or format host commands (e.g., commands received from a host) into device commands (e.g., commands associated with operation of a memory array, etc.), or generate device commands (e.g., to accomplish various memory management functions) for array controller 235 or one or more other components of memory device 210.

Memory manager 225 can include a set of management tables 230 configured to maintain various information associated with one or more component of memory device 210 (e.g., various information associated with a memory array or one or more memory cells coupled to memory processing device 215). For example, management tables 230 can include information regarding block age, block erase count, error history, or one or more error counts (e.g., a write operation error count, a read bit error count, a read operation error count, an erase error count, etc.) for one or more blocks of memory cells coupled to memory processing device 215. In certain examples, if the number of detected errors for one or more of the error counts is above a threshold, the bit error can be referred to as an uncorrectable bit error. Management tables 230 can maintain a count of correctable or uncorrectable bit errors, among other things.

Array controller 235 can include, among other things, circuitry or components configured to control memory operations associated with writing data to, reading data from, or erasing one or more memory cells of memory device 210 coupled to memory processing device 215. The memory operations can be based on, for example, host commands received from host device 205, or internally generated by memory manager 225 (e.g., in association with wear leveling, error detection or correction, etc.).

Array controller 235 can include an error correction code (ECC) component 240, which can include, among other things, an ECC engine or other circuitry configured to detect or correct errors associated with writing data to or reading data from one or more memory cells of memory device 210 coupled to memory processing device 215. Memory processing device 215 can be configured to actively detect and recover from error occurrences (e.g., bit errors, operation errors, etc.) associated with various operations or storage of data, while maintaining integrity of the data transferred between host device 205 and memory device 210, or maintaining integrity of stored data, and can remove (e.g., retire) failing memory resources (e.g., memory cells, memory arrays, pages, blocks, etc.) to prevent future errors.

Memory array 220 can include several memory cells arranged in, for example, a number of devices, planes, sub-blocks, blocks, or pages. As one example, a 48 GB TLC NAND memory device can include 18,592 bytes (B) of data per page (16,384+2208 bytes), 1536 pages per block, 548 blocks per plane, and 4 or more planes per device. As another example, a 32 GB MLC memory device (storing two bits of data per cell (i.e., 4 programmable states)) can include 18,592 bytes (B) of data per page (16,384+2208 bytes), 1024 pages per block, 548 blocks per plane, and 4 planes per device, but with half the required write time and twice the program/erase (P/E) cycles as a corresponding TLC memory device. Other examples can include other numbers or arrangements. In some examples, a memory device, or a portion thereof, may be selectively operated in SLC mode, or in a desired MLC mode (such as TLC, QLC, etc.).

In operation, data is typically written to or read from NAND memory device 210 in pages and erased in blocks. However, one or more memory operations (e.g., read, write, erase, etc.) can be performed on larger or smaller groups of memory cells, as desired. The data transfer size of NAND memory device 210 is typically referred to as a page; whereas the data transfer size of a host is typically referred to as a sector.

Although a page of data can include a number of bytes of user data (e.g., a data payload including a number of sectors of data) and its corresponding metadata, the size of the page often refers only to the number of bytes used to store the user data. As an example, a page of data having a page size of 4 KB may include 4 KB of user data (e.g., 8 sectors assuming a sector size of 512 B) as well as a number of bytes (e.g., 32 B, 54 B, 224 B, etc.) of metadata corresponding to the user data, such as integrity data (e.g., error detecting or correcting code data), address data (e.g., logical address data, etc.), or other metadata associated with the user data.

Different types of memory cells or memory arrays 220 can provide for different page sizes or may require different amounts of metadata associated therewith. For example, different memory device types may have different bit error rates, which can lead to different amounts of metadata used to ensure integrity of the page of data (e.g., a memory device with a higher bit error rate may require more bytes of error correction code data than a memory device with a lower bit error rate). As an example, a multi-level cell (MLC) NAND flash device may have a higher bit error rate than a corresponding single-level cell (SLC) NAND flash device. As such, the MLC device may require more metadata bytes for error data than the corresponding SLC device.

Memory devices, such as but not limited to memory device 210 of FIG. 2, can be subjected to a new method of writing preload data, which is user data for an application to which the memory devices are designed. Memory device 210 can be a NAND storage memory device. This method may be implemented in a number of variations of the method or permutations of the features of the method. Such a method can include writing the exact same data on top of existing data at least twice, where the data is preload data. Writing the exact same data on top of existing data is performed on the same set of memory cells of the memory device. The second or later writes serve as a touch-up for data refresh of the preload data to gain RWB margin and improve retention slope before reflow. In addition, there is no erase in between the two or multiple writes of the same data on top of the same data.

The second write can start according to a number of different procedures. One procedure for the start of a second write can be performed after all the target blocks, in which to program the preload data, have been written to with user preload data for the first time. In various embodiments, the preload data can fill the targeted blocks. In another procedure for the start of second writes, the second write can start after some portion of the target blocks are done writing user data. In another procedure for the start of second writes, the second write can start after a cumulative time has met a target value. In procedures for first writes and second writes, after a second write on a selected block of the target blocks, the second writes of preload data to target blocks can start alternating between the first write on the blocks that don't have user data yet and second write on the blocks of the target blocks that have existing preload data.

The second writes, which are touch-up data refreshes, can be selective. For example, to save touch-up time, the second write can be performed on only higher V_{T} states. The selection of the higher V_{T} states can depend on the type of MLC memory device used. The selection of the higher V_{T} states can also be determined using manufacturing data of the memory device prior to being allocated to a structure for user application in a product. The second writes can be selectively performed only on the weaker access line that has a lower RWB margin, that is, the second writes can target the weaker word lines that have more charge loss after the high temperature. Determination of the lower RWBs can be based on extracted factory data, collected before allocation to a product. In another approach, the weaker word lines can be checked in real time to determine higher bit error rate using firmware of the memory system in which the memory device is implemented, where the second writes of preload are performed on manufactured memory devices before reflow of the memory devices to the system boards of the applications to which the memory devices are designed.

FIG. 3 is a flow diagram of an embodiment of an example method 300 of preparing a memory device with preload data followed by performing a reflow of the memory device to a structure for an application to which the memory device is implemented. A host device can provide the preload data to a memory system controller for the memory device. The memory system controller can be a processing device for multiple memory devices such as a processing device of a managed memory system, for example, a managed NAND system. The memory system controller sends the preload data to the memory device, such as a NAND memory device, along with a program command to the memory device. The program command can be implemented as a special program that directs touch-up (re-programming) of the preload data without an erase between programming and touching up. A memory controller within the memory device can direct programming and touching up in response to receiving the preload data and instructions from the memory system controller external to the memory device.

At 310, targeted memory blocks of a memory device are erased, where the memory device has an array arranged as one or more blocks of memory cells. The memory cells can be MLCs. In various embodiments, method 300 can be implemented without first erasing the targeted memory blocks, based on the status of the memory device.

At 320, preload data is programmed into the targeted memory blocks until the targeted memory blocks are programmed with the preload data. The programming can be conducted until all of the preload data is programmed into the targeted memory blocks.

At 330, the exact same preload data is re-programmed on top of the existing preload data to the targeted memory blocks without an erase in between programming and re-programming. Re-programming on top of the existing preload data is performed on the same set of memory cells of the targeted memory blocks. The re-programming of the preload data over the programmed preload data in the targeted memory blocks can be performed after the programming of all of the preload data in the targeted memory blocks has been completed. A memory controller within the memory device can direct the programming and re-programming of the preload data in the set of memory cells of the targeted blocks within the array of the memory device.

At 340, a reflow process is performed on the memory device. The memory device can be subjected to the reflow process after the targeted blocks are programmed with the preload data and each block of the targeted blocks has been reprogrammed at least once. The reflow process can include an infrared reflow process. The touch-up of method 300 can extend the retention lifetime of the memory device and can be faster than some conventional methods.

In various embodiments, a memory device can comprise an array arranged as one or more blocks of memory cells and a memory controller, including processing circuitry, to cause the memory device to perform operations. The memory controller can be within the memory device to direct operations regarding loading preload data and touching up the preload data. The operations can include programming preload data into targeted blocks of the one or more blocks until the targeted blocks are programmed with the preload data and re-programming the preload data over the programmed preload data in the targeted blocks in a same set of memory cells, without an erase between programming and re-programming the preload data. The operations can include erasing the targeted blocks before programming the preload data. The programming of the preload data can be in response to receiving the preload data and a command to program and re-program the preload data in the same set of memory cells without an erase between programming and re-programming the preload data.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the re-programming of the preload data over the programmed preload data being performed more than once without an erase between each of the re-programming the preload data. Variations can include the preload data for the one or more targeted blocks partially filling the one or more targeted blocks of the memory array. In an embodiment, the array of the memory device can be structured in a three-dimensional NAND configuration.

FIG. 4 is a flow diagram of an embodiment of another example method 400 of preparing a memory device with preload data followed by performing a reflow of the memory device to a structure for an application to which the memory device is implemented. A host device can provide the preload data to a memory controller for the memory device. The memory controller can be a processing device for multiple memory devices such as a memory processing device of a managed memory system, for example, a managed NAND system.

At 410, targeted memory blocks of a memory device are erased, where the memory device has an array arranged as one or more memory blocks of memory cells. The memory cells can be MLCs. In various embodiments, method 400 can be implemented without first erasing the targeted memory blocks, based on the status of the memory device.

At 420, preload data is programmed into the targeted memory blocks until specified portions of the targeted memory blocks are programmed. The preload data can be programmed into the targeted memory blocks to meet a targeted delay time. At 430, the exact same data is re-programmed on top of the existing preload data to a first programmed memory block of the targeted memory blocks to refresh the data without an erase in between programming and re-programming. A memory controller within the memory device can direct the programming and re-programming of the preload data in the set of memory cells of the targeted blocks within the array of the memory device.

At 440, the preload data is operated on in an alternating manner. Preload data can be programmed to a new memory block of the targeted memory blocks, where the new memory block is a memory block of the targeted memory blocks other than the first programmed memory block for which a re-programming has been performed. Touch-up preload data refresh is performed on earlier programmed memory blocks. After a first re-program of the first programmed memory block, which is a second write to the first programmed memory block, the procedure can include starting the alternating between the programming (first write) on memory blocks that don't have preload data yet and re-programming (second write) on the memory blocks of the targeted memory blocks that have existing preload data. Existing preload data of a targeted memory block is preload data first programmed into the targeted memory block in the procedure. Data that is not preload data in a targeted memory block at the beginning of the procedure can be erased at the beginning of the procedure.

At 450, once all the targeted memory blocks are programmed with the preload data and each memory block of the target memory blocks has been touch-up refreshed at least once, a reflow process is performed. The reflow process can include an infrared reflow process. The touch-up of method 400 can extend the retention lifetime of the memory device and can be faster than some conventional methods.

Variations of method 400 or methods similar to method 400 can include a number of different embodiments that may be combined depending on the application of such methods and/or the architecture of systems including an electronic device in which such methods are implemented. Such methods can include the re-programming of the preload data over the programmed preload data in the targeted blocks being performed after a number of blocks of the targeted blocks have been programmed with the preload data for the number of blocks. Variations can include the re-programming of the preload data over the programmed preload data in the targeted blocks being performed after a specified delay time has met a target value. Variations can include the programming of preload data and re-programming of the preload data over the programmed preload data in the targeted blocks being performed by first programming reload data for the first block and re-programming the reload data over the preload data in the first block, followed by alternating programming of additional blocks of the targeted blocks between first programming of the additional blocks with preload data for the additional blocks and re-programming the preload data for the additional blocks. The alternating of programming and re-programming can be performed in a sequential manner or a non-sequential manner.

In various embodiments, a memory device can comprise an array arranged as one or more blocks of memory cells and a memory controller, including processing circuitry, to cause the memory device to perform operations. The memory controller can be within the memory device to direct operations regarding loading preload data and touching up the preload data. The operations can include programming preload data into a first block of targeted blocks until the preload data for the first block has been programmed into the first block, where the targeted blocks include a first block and additional blocks. The operations include re-programming the preload data over the programmed preload data in a same set of memory cells of the first block of the targeted blocks, without an erase between programming and re-programming the preload data in the first block. After re-programming the preload data over the preload data in the first block, the operations can include alternating programming the additional blocks between first programming of the additional blocks with preload data for the additional blocks and re-programming the preload data for the additional blocks. The alternating programming and re-programming can be sequential or non-sequential. Some blocks of the target blocks can be re-programmed more times than other blocks of the target blocks. The operations can include erasing the targeted blocks before programming the preload data for the first block. The programming of the preload data in the targeted blocks can be performed in response to receiving the preload data and a command to program and re-program the preload data in the same set of memory cells of the targeted blocks without an erase between programming and re-programming the preload data in the same set of memory cells.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the re-programming of the first block starting after a delay time for the re-programming of the first block has met a target value. Variations can include the re-programming of the preload data over the programmed preload data in the same set of memory cells being performed more than once without an erase between each of the re-programming the preload data.

Variations of the operations can include, after re-programming the preload data over the preload data in the first block, programming and re-programming preload data for a second block of the targeted blocks over the preload data in the second block, without an erase between programming and re-programming the preload data for the second block, with the alternating programming of additional blocks beginning after re-programming the preload data over the preload data in the second block.

Variations of the operations can include, prior to performing the alternating programming of additional blocks, programming preload data into a second block of the targeted blocks until the first block and the second block are programmed with the preload data for the first block and the second block and re-programming the preload data over the programmed preload data in the first block and the second block of the targeted blocks in a same set of memory cells, without an erase between programming and re-programming the preload data in the first block and the second block of the targeted blocks. In this manner, the preload data in in the first block and the second block can be programed and re-programmed in a series of partial programing and re-programming that can alternate between the first and second block. The alternating processing of the first block and the second block can be completed before programming of additional blocks of the targeted blocks.

FIG. 5 is a flow diagram of an embodiment of another example method 500 of preparing a memory device with preload data followed by performing a reflow of the memory device to a structure for an application to which the memory device is implemented. A host device can provide the preload data to a memory controller for the memory device. The memory controller can be a processing device for multiple memory devices such as a memory processing device of a managed memory system, for example, a managed NAND system.

At 510, preload data is programmed into targeted memory blocks of a memory device, where the memory device has an array arranged as one or more blocks of memory cells. The memory cells can be MLCs. In various embodiments, method 500 can be implemented by first erasing the targeted memory blocks. In various embodiments, method 500 can be implemented without first erasing the targeted memory blocks, based on the status of the memory device.

At 520, memory blocks of the target blocks are selected for re-programming. At 530, the preload data for the selected memory blocks is re-programmed over the programmed preload data in the selected memory blocks in a same set of memory cells of the selected memory blocks, without an erase between programming and re-programming the preload data in the selected memory blocks. The memory device can be subjected to a reflow process after the targeted blocks are programmed with the preload data and each selected block of the target blocks has been reprogrammed at least once. The reflow process can include an infrared reflow process.

Variations of method 500 or methods similar to method 500 can include a number of different embodiments that may be combined depending on the application of such methods and/or the architecture of systems including an electronic device in which such methods are implemented. Such methods can include selecting the blocks of the target blocks for re-programming by selecting blocks having memory cells with threshold voltage states above a specified state. Re-programming the preload data for the selected blocks over the programmed preload data in the selected blocks can be performed only on the memory cells having threshold voltage states above the specified state. Variations can include selecting the blocks of the target blocks for re-programming by selecting blocks having memory cells with a RWB margin below a threshold for a RWB margin.

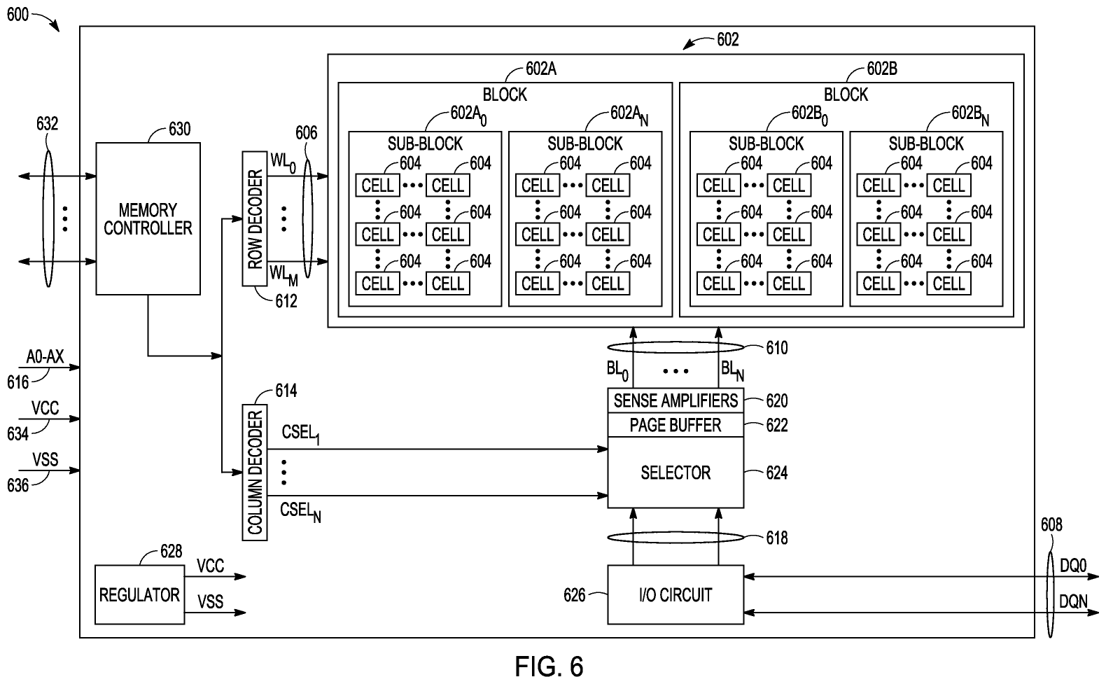

FIG. 6 illustrates an example block diagram of a memory device 600 including a memory array 602 having a plurality of memory cells 604, and one or more circuits or components to provide communication with or perform one or more memory operations on memory array 602. Memory device 600 can include a row decoder 612, a column decoder 614, sense amplifiers 620, a page buffer 622, a selector 624, an input/output (I/O) circuit 626, and a memory controller 630. Memory device 600 can be programmed with preload data prior to reflow to a structure on which memory device 600 is positioned in operation of a user application.

Memory cells 604 of memory array 602 can be arranged in blocks, such as first and second blocks 602A, 602B. Each block can include sub-blocks. For example, first block 602A can include first and second sub-blocks 602A₀, 602Aₙ, and second block 602B can include first and second sub-blocks 602B₀, 602Bₙ. Each sub-block can include a number of physical pages, each page including a number of memory cells 604. Although illustrated herein as having two blocks, each block having two sub-blocks, and each sub-block having a number of memory cells 604, in other examples, memory array 602 can include more or fewer blocks, sub-blocks, memory cells, etc. In other examples, memory cells 604 can be arranged in a number of rows, columns, pages, sub-blocks, blocks, etc., and accessed using, for example, access lines 606, first data lines 610, or one or more select gates, source lines, etc.

Memory controller 630 can control memory operations of memory device 600 according to one or more signals or instructions received on control lines 632, including, for example, one or more clock signals or control signals that indicate a desired operation (e.g., write, read, erase, etc.), or address signals (A0-AX) received on one or more address lines 616. One or more devices external to memory device 600 can control the values of the control signals on control lines 632, or address signals on address line 616. Examples of devices external to memory device 600 can include, but are not limited to, a host, a memory controller, a processor, or one or more circuits or components not illustrated in FIG. 6.

Memory controller 630 can receive preload data and a program command to program the preload data into memory device 600, where preload data is user data to be placed in memory device 600 prior to memory device 600 being reflowed onto a structure for the system for which the memory device is to be operational in a product of the user. The structure can be implemented as a platform such as, but not limited, to a printed circuit board or a system motherboard. Memory controller 630 can be implemented such that one of several program/re-program techniques, as taught herein, can be selected to be executed by memory controller 630. The program/re-program techniques can include techniques associated with method 300 of FIG. 3, method 400 of FIG. 4, method 500 of FIG. 5, and variations thereof. The program command to memory controller 630 to preload data, according to a program/re-program technique, can be a special program command to re-program the preload data to the same memory cells to which the preload was first programmed. The special program command can identify that the re-programming is to be performed without an erase between the programming and the re-programming on top of the memory cells in which the preload data was first programmed.

Memory device 600 can use access lines 606 and first data lines 610 to transfer data to (e.g., write or erase) or from (e.g., read) one or more of memory cells 604. Row decoder 612 and column decoder 614 can receive and decode the address signals (A0-AX) from address line 616, can determine which of memory cells 604 are to be accessed, and can provide signals to one or more of access lines 606 (e.g., one or more of a plurality of word lines (WL0-WLm)) or first data lines 610 (e.g., one or more of a plurality of bit lines (BL0-BLn)), such as described above.

Memory device 600 can include sense circuitry, such as the sense amplifiers 620, configured to determine the values of data on (e.g., read), or to determine the values of data to be written to, memory cells 604 using first data lines 610. For example, in a selected string of memory cells 604, one or more of sense amplifiers 620 can read a logic level in the selected memory cell 604 in response to a read current flowing in memory array 602 through the selected string to data lines 610.

One or more devices external to memory device 600 can communicate with memory device 600 using I/O lines (DQ0-DQN) 608, address lines 616 (A0-AX), or control lines 632. Input/output (I/O) circuit 626 can transfer values of data in or out of memory device 600, such as in or out of page buffer 622 or memory array 602, using I/O lines 608, according to, for example, control lines 632 and address lines 616. Page buffer 622 can store data received from the one or more devices external to memory device 600 before the data is programmed into relevant portions of memory array 602 or can store data read from memory array 602 before the data is transmitted to the one or more devices external to memory device 600.

Column decoder 614 can receive and decode address signals (A0-AX) into one or more column select signals (CSEL1-CSELn). Selector 624 (e.g., a select circuit) can receive the column select signals (CSEL1-CSELn) and select data in page buffer 622 representing values of data to be read from or to be programmed into memory cells 604. Selected data can be transferred between page buffer 622 and I/O circuit 626 using second data lines 618.

Memory controller 630 can receive positive and negative supply signals, such as a supply voltage (Vcc) 634 and a negative supply (Vss) 636 (e.g., a ground potential), from an external source or supply (e.g., an internal or external battery, an AC-to-DC converter, etc.). In certain examples, memory controller 630 can include a regulator 628 to internally provide positive or negative supply signals.

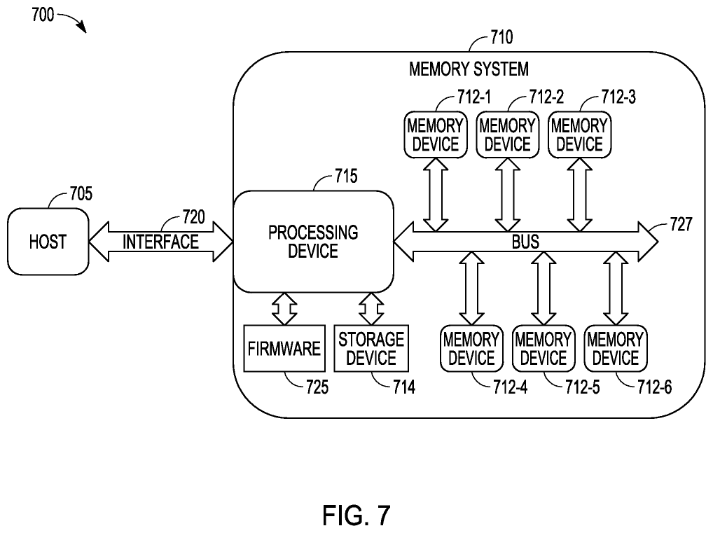

FIG. 7 is a block diagram of an embodiment of example system 700 including a host 705 that operates with a memory system 710 having one or more memory devices having preload data for the application for which memory system 710 is implemented. Host 705 is coupled to memory system 710 by an interface 720. Memory system 710 can include a processing device 715 coupled to memory devices 712-1, 712-2, 712-3, 712-4, 712-5, and 712-6 by a bus 727, where each memory device has an array arranged as one or more blocks of memory cells. Processing device 715 can be structured as a memory system controller for memory system 710. Memory devices 712-1, 712-2, 712-3, 712-4, 712-5, and 712-6 may be NAND memory devices. Though six memory devices are shown in FIG. 7, memory system 710 can be implemented with more or fewer than six memory devices, that is, memory system 710 can comprise one or more memory devices. The memory devices can be realized in a number of formats including, but not limited to, a plurality of memory dies. Processing device 715 can include processing circuitry or be structured as one or more processors. Processing device 715 can be implemented in a number of different formats. Processing device 715 can include processing circuitry that can be structured with a digital signal processor (DSP), an application-specific integrated circuit (ASIC), other type of processing circuit, including a group of processors or multi-core devices, or combinations thereof.

Memory system 710 can comprise firmware 725 having code executable by processing device 715 to at least manage the memory devices 712-1, 712-2, 712-3, 712-4, 712-5, and 712-6. Firmware 725 can reside in a storage device of memory system 710 coupled to processing device 715. Firmware 725 can be coupled to the processing device 715 using bus 727 or some other interface on the memory system 710. Alternatively, firmware 725 can reside in processing device 715 or can be distributed in memory system 710 with firmware components, such as but not limited to code, including one or more components in processing device 715. Firmware 725 can include code having instructions, executable by processing device 715, to operate on memory devices 712-1, 712-2, 712-3, 712-4, 712-5, and 712-6. The instructions can include instructions to execute operations to prepare one or more of memory devices 712-1, 712-2, 712-3, 712-4, 712-5, and 712-6 with preload data, where the execution of the operations can be followed by performing a reflow of the one or more of memory devices 712-1, 712-2, 712-3, 712-4, 712-5, and 712-6 to a structure for an application to which memory system 710 is implemented.

System 700 and its components can be structured in a number of different arrangements. For example, system 700 can be arranged with a variation of the type of components that comprise host 705, interface 720, memory system 710, memory devices 712-1, 712-2, 712-3, 712-4, 712-5, and 712-6, processing device 715, and bus 727. Host 705 can comprise one or more processors, which can vary in type. Interface 720 can be arranged as, but not limited to, a PCle interface. Memory system 710 can be, but is not limited to, a SSD. Memory devices 712-1, 712-2, 712-3, 712-4, 712-5, and 712-6 can be NAND memory devices. Processing device 715 can include or be structured as one or more types of processors compatible with memory devices 712-1, 712-2, 712-3, 712-4, 712-5, and 712-6. Bus 727 can be an open NAND flash interface (ONFI) bus for memory devices 712-1, 712-2, 712-3, 712-4, 712-5, and 712-6 being NAND flash memory devices. A storage device 714 can be implemented to provide data or parameters used in maintence of memory system 710. Storage device 714 can include a RAM. Though storage device 714 is external to processing device 715 in memory system 710 in FIG. 7, storage device 714 may be integrated into processing device 715. Storage device 714 can be coupled to bus 727 for communication with other components of memory system 710. Alternatively, storage device 714 can be coupled with processing device 715 in which processing device 715 handles communications between storage device 714 and other components of the memory system 710. Storage device 714 can be coupled to bus 727 and to processing device 715.

In various embodiments, firmware 725 can have instructions, executable by processing device 715, to operate on multiple memory devices of the memory devices 712-1, 712-2, 712-3, 712-4, 712-5, and 712-6. The operations can include operations to perform, in conjunction with a memory controller within a selected memory device of memory devices 712-1, 712-2, 712-3, 712-4, 712-5, or 712-6 such as memory controller 630 of FIG. 6, one or more functions of method 300 of FIG. 3, method 400 of FIG. 4, or method 500 of FIG. 5.

Host 705 can provide preload data to processing device 715, where processing device 715 is a memory system controller of memory system 710. Processing device 715 can send the preload data to target blocks of memory cells of one or more of memory devices 712-1, 712-2, 712-3, 712-4, 712-5, or 712-6 along with a program command to the one or more of memory devices 712-1, 712-2, 712-3, 712-4, 712-5, or 712-6 to program the preload data into the target blocks of memory cells of the one or more of memory devices 712-1, 712-2, 712-3, 712-4, 712-5, or 712-6. The one or more of memory devices 712-1, 712-2, 712-3, 712-4, 712-5, or 712-6 can program the target blocks. Alternatively, target memory cells can be programmed with preload data by programming the preload data according to access lines, WL, for example. For a programming of preload data, the program command can be a special program command to perform re-programming of the preload data on the programmed existing preload data without an erase between the programming and re-programming. Re-programming of the preload data, using this special program command, is a writing of the exact same preload data on the same set of memory cells on which the preload data was programmed. Various procedures of programming and re-programming the same preload data in the same set of memory cells, as taught herein, can be implemented. Tracking the programming and re-programming of the same data can be monitored within the selected memory devices of the one or more of memory devices 712-1, 712-2, 712-3, 712-4, 712-5, or 712-6. Alternatively, the tracking of the programming and re-programming of the same data can be monitored within operation of processing device 715 and firmware 725. In some embodiments, the programming/re-programming procedure can be selectable within memory system 710 or by host 705.

Processing device 715 can execute instructions stored on one or more components in memory system 710, which instructions, when executed by processing device, cause memory system 710 to perform operations. The operations can include programming preload data into targeted blocks of memory devices 712-1, 712-2, 712-3, 712-4, 712-5, and 712-6 and re-programming the preload data over the programmed preload data in the targeted blocks in a same set of memory cells, without an erase between programming and re-programming the preload data in each targeted block. Processing device 715 can execute such instructions in conjunction with the memory controller of memory devices 712-1, 712-2, 712-3, 712-4, 712-5, and 712-6 containing targeted blocks.

The programming and re-programming of the preload data, via processing device 715 and associated memory controller of the appropriate memory devices, can be performed in a number of different techniques. The re-programming of the preload data over the programmed preload data in the targeted blocks can be performed after the programming of the preload data in the targeted blocks has been completed. The re-programming of the preload data over the programmed preload data in the targeted blocks can be performed after a number of blocks of the targeted blocks have been programmed with the preload data for the number of blocks. The re-programming of the preload data over the programmed preload data in the targeted blocks can be performed after a specified delay time has met a target value. In memory system 710, the programming of preload data and re-programming of the preload data over the programmed preload data in the targeted blocks can be performed by first programming reload data for a first block and re-programming the reload data over the preload data in the first block, followed by alternating programming of additional blocks of the targeted blocks between first programming of the additional blocks with preload data for the additional blocks and re-programming the preload data for the additional blocks.

FIG. 8 illustrates a block diagram of an embodiment of an example machine 800 having one or more memory devices having preload data as discussed herein. In alternative embodiments, machine 800 can operate as a standalone device or can be connected (e.g., networked) to other machines. In a networked deployment, machine 800 can operate in the capacity of a server machine, a client machine, or both in server-client network environments. In an example, machine 800 can act as a peer machine in peer-to-peer (P2P) (or other distributed) network environment. Machine 800 can be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more methodologies such as cloud computing, software as a service (SaaS), other computer cluster configurations.

Examples, as described herein, can include, or can operate by, logic, components, devices, packages, or mechanisms. Circuitry is a collection (e.g., set) of circuits implemented in tangible entities that include hardware (e.g., simple circuits, gates, logic, etc.). Circuitry membership can be flexible over time and underlying hardware variability. Circuitries include members that can, alone or in combination, perform specific tasks when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a computer readable medium physically modified (e.g., magnetically, electrically, moveable placement of invariant massed particles, etc.) to store instructions of the specific operation. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components can be used in more than one member of more than one circuitry.

The machine 800 can include a hardware processor 850 (e.g., a CPU, a GPU, a hardware processor core, or any combination thereof), a main memory 854, and a static memory 856, some or all of which can communicate with each other via an interlink 858 (e.g., bus). Machine 800 can further include a display device 860, an input device 862, which can be an alphanumeric input device (e.g., a keyboard), and a user interface (UI) navigation device 864 (e.g., a mouse). In an example, display device 860, input device 862, and UI navigation device 864 can be a touch screen display. Machine 800 can additionally include a mass storage device (e.g., drive unit) 851, a network interface device 853, a signal generation device 868, and one or more sensors 866, such as a global positioning system (GPS) sensor, compass, accelerometer, or other sensor. Machine 800 can include an output controller 869, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 800 can include one or more machine-readable media on which is stored one or more sets of data structures or instructions 855 (e.g., software, microcode, or other type of instructions) embodying or utilized by machine 800 to perform any one or more of the techniques or functions for which machine 800 is designed. Instructions 855 can reside, completely or at least partially, within main memory 854, within static memory 856, or within hardware processor 850 during execution thereof by machine 800. In an example, one or any combination of hardware processor 850, main memory 854, static memory 856, or mass storage device 851 can constitute the machine-readable media on which is stored one or more sets of data structures or instructions. Various ones of hardware processor 850, main memory 854, static memory 856, or mass storage device 851 can include instructions for programming/re-programing preload data, as discussed herein.

While an example machine-readable medium is illustrated as a single medium, the term “machine-readable medium” can include a single medium or multiple media (e.g., a centralized or distributed database, or associated caches and servers) configured to store instructions 855 or data. The term “machine-readable medium” can include any medium that is capable of storing instructions for execution by machine 800 and that cause machine 800 to perform any one or more of the techniques to which machine 800 is designed, or that is capable of storing data structures used by or associated with such instructions. Non-limiting machine-readable medium examples can include solid-state memories, optical media, and magnetic media. Specific examples of non-transitory machine-readable media can include non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Instructions 855 (e.g., software, programs, an operating system (OS), etc.) or other data stored on mass storage device 851 can be accessed by main memory 854 for use by hardware processor 850. Main memory 854 (e.g., a DRAM) is typically fast, but volatile, and thus a different type of storage than mass storage device 851 (e.g., an SSD), which is suitable for long-term storage, including while in an “off” condition. Instructions 855 or data in use by a user or machine 800 are typically loaded in main memory 854 for use by hardware processor 850. When main memory 854 is full, virtual space from mass storage device 851 can be allocated to supplement main memory 854; however, because mass storage device 851 is typically slower than main memory 854, and write speeds are typically at least twice as slow as read speeds, use of virtual memory can greatly reduce user experience due to storage device latency (in contrast to main memory 854, e.g., a DRAM). Further, use of mass storage device 851 for virtual memory can greatly reduce the usable lifespan of mass storage device 851.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC devices are attached to a circuit board and considered a component of the host device, with read speeds that rival SATA-based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 855 can further be transmitted or received over a network 859 using a transmission medium via signal generation device 868 or network interface device 853 utilizing any one of a number of transfer protocols (e.g., frame relay, Internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMAX®), IEEE 802.15.4 family of standards, peer-to-peer (P2P) networks, among others. In an example, signal generation device 868 or network interface device 853 can include one or more physical jacks (e.g., Ethernet, coaxial, or phone jacks) or one or more antennas to connect to network 859. In an example, signal generation device 868 or network interface device 853 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 800 or data to or from machine 800, and can include instrumentalities to propagate digital or analog communications signals to facilitate communication of such instructions, which instructions may be implemented by software or data.

The following are example embodiments of systems, devices, and methods, in accordance with the teachings herein.

An example memory device 1 can comprise an array arranged as one or more blocks of memory cells and a memory controller including processing circuitry to cause the memory device to perform operations. The operations can include programming preload data into targeted blocks of the one or more blocks until the targeted blocks are programmed with the preload data, and re-programming the preload data over the programmed preload data in the targeted blocks in a same set of memory cells, without an erase between programming and re-programming the preload data.

An example memory device 2 can include features of example memory device 1 and can include the operations including erasing the targeted blocks before programming the preload data.

An example memory device 3 can include features of any features of the preceding example memory devices and can include programming the preload data in response to receiving the preload data and a command to program and re-program the preload data in the same set of memory cells without an erase between programming and re-programming the preload data.

An example memory device 4 can include features of any of the preceding example memory devices and can include the re-programming of the preload data over the programmed preload data being performed more than once without an erase between each of the re-programming the preload data.

An example memory device 5 can include features of any of the preceding example memory devices and can include the preload data for the one or more targeted blocks partially filling the one or more targeted blocks of the array.

An example memory device 6 can include features of any of the preceding example memory devices and can include the array being structured in a three-dimensional NAND configuration.

In an example memory device 7, any of the memory devices of example memory devices 1 to 6 may include memory devices incorporated into an electronic apparatus further comprising a host processor and a communication bus extending between the host processor and the memory device.

In an example memory device 8, any of the memory devices of example memory devices 1 to 7 may be modified to include any structure presented in another of example memory device 1 to 7.

In an example memory device 9, any apparatus associated with the memory devices of example memory devices 1 to 8 may further include a machine-readable storage device configured to store instructions as a physical state, wherein the instructions may be used to perform one or more operations of the apparatus.

In an example memory device 10, any of the memory devices of example memory devices 1 to 9 may be operated in accordance with any of the below example methods 1 to 12.

An example memory device 11 can comprise an array arranged as blocks of memory cells and a memory controller including processing circuitry to cause the memory device to perform operations. The operations can include programming preload data into a first block of targeted blocks until the preload data for the first block has been programmed into the first block, the targeted blocks including a first block and additional blocks; re-programming the preload data over the programmed preload data in a same set of memory cells of the first block of the targeted blocks, without an erase between programming and re-programming the preload data in the first block; and after re-programming the preload data over the preload data in the first block, alternating programming of additional blocks between first programming of the additional blocks with preload data for the additional blocks and re-programming the preload data for the additional blocks.

An example memory device 12 can include features of example memory device 11 and can include the operations including erasing the targeted blocks before programming the preload data for the first block.

An example memory device 13 can include features of any features of the preceding example memory devices 11 to 12 and can include the re-programming of the first block starting after a delay time for the re-programming of the first block has met a target value.

An example memory device 14 can include features of any of the preceding example memory devices 11 to 13 and can include the programming of the preload data in the targeted blocks being in response to receiving the preload data and a command to program and re-program the preload data in the same set of memory cells of the targeted blocks without an erase between programming and re-programming the preload data in the same set of memory cells.

An example memory device 15 can include features of any of the preceding example memory devices 11 to 14 and can include the re-programming of the preload data over the programmed preload data in the same set of memory cells being performed more than once without an erase between each of the re-programming the preload data.

An example memory device 16 can include features of any of the preceding example memory devices 11 to 15 and can include the operations including, after re-programming the preload data over the preload data in the first block, programming and re-programming preload data for a second block of the targeted blocks over the preload data in the second block, without an erase between programming and re-programming the preload data for the second block, with the alternating programming of additional blocks beginning after re-programming the preload data over the preload data in the second block.

An example memory device 17 can include features of any of the preceding example memory devices 11 to 16 and can include the operations including, prior to performing the alternating programming of additional blocks: programming preload data into a second block of the targeted blocks until the first block and the second block are programmed with the preload data for the first block and the second block; and re-programming the preload data over the programmed preload data in the first block and the second block of the targeted blocks in a same set of memory cells, without an erase between programming and re-programming the preload data in the first block and the second block of the targeted blocks.

In an example memory device 18, any of the memory devices of example memory devices 11 to 17 may include memory devices incorporated into an electronic apparatus further comprising a host processor and a communication bus extending between the host processor and the memory device.

In an example memory device 19, any of the memory devices of example memory devices 11 to 18 may be modified to include any structure presented in another of example memory device 11 to 18.

In an example memory device 20, any apparatus associated with the memory devices of example memory devices 11 to 19 may further include a machine-readable storage device configured to store instructions as a physical state, wherein the instructions may be used to perform one or more operations of the apparatus.

In an example memory device 21, any of the memory devices of example memory devices 11 to 20 may be operated in accordance with any of the below example methods 1 to 12.

An example memory system 1 can comprise memory devices, where each memory device has an array arranged as one or more blocks of memory cells, and a processing device, including processing circuitry, coupled to the memory devices. The processing device can execute instructions stored on one or more components in the memory system, which instructions, when executed by the processing device, cause the memory system to perform operations. The operations can comprise programming preload data into targeted blocks of the memory devices and re-programming the preload data over the programmed preload data in the targeted blocks in a same set of memory cells, without an erase between programming and re-programming the preload data in each targeted block.

An example memory system 2 can include features of preceding example memory system 1 and can include the re-programming of the preload data over the programmed preload data in the targeted blocks being performed after the programming of the preload data in the targeted blocks has been completed.

An example memory system 3 can include features of any of the preceding example memory systems and can include the re-programming of the preload data over the programmed preload data in the targeted blocks being performed after a number of blocks of the targeted blocks have been programmed with the preload data for the number of blocks.

An example memory system 4 can include features of any of the preceding example memory systems and can include the re-programming of the preload data over the programmed preload data in the targeted blocks being performed after a specified delay time has met a target value.

An example memory system 5 can include features of any features of the preceding example memory systems and can include the programming of preload data and re-programming of the preload data over the programmed preload data in the targeted blocks being performed by first programming reload data for a first block and re-programming the reload data over the preload data in the first block, followed by alternating programming of additional blocks of the targeted blocks between first programming of the additional blocks with preload data for the additional blocks and re-programming the preload data for the additional blocks.

In an example memory system 6, any of the memory systems of example memory systems 1 to 5 may include one or more memory systems incorporated into an electronic apparatus further comprising a host processor and a communication bus extending between the host processor and the one or more memory systems.

In an example memory system 7, any of the memory systems of example memory systems 1 to 6 may be modified to include any structure presented in another of example memory systems 1 to 6.

In an example memory system 8, any apparatus associated with the memory systems of example memory systems 1 to 7 may further include a machine-readable storage device configured to store instructions as a physical state, wherein the instructions may be used to perform one or more operations of the apparatus.

In an example memory system 9, any of the memory systems of example memory systems 1 to 8 may be operated in accordance with any of the methods of the below example methods 1 to 12.

An example method 1 can comprise programming preload data into targeted blocks of a memory device, where the memory device has an array arranged as one or more blocks of memory cells; re-programming the preload data over the programmed preload data in the targeted blocks in a same set of memory cells, without an erase between programming and re-programming the preload data; and subjecting the memory device to a reflow process after the targeted blocks are programmed with the preload data and each block of the targeted blocks has been reprogrammed at least once.

An example method 2 can include features of example method 1 and can include erasing the targeted blocks before programming the preload data.

An example method 3 can include features of any of the preceding example methods and can include subjecting the memory device to the reflow process to include subjecting the memory device to an infrared reflow process.

An example method 4 can include features of example method 3 and any of the preceding example methods and can include the re-programming of the preload data over the programmed preload data in the targeted blocks being performed after the programming of the preload data in the targeted blocks has been completed.

An example method 5 can include features of any of the preceding example methods and can include the re-programming of the preload data over the programmed preload data in the targeted blocks being performed after a number of blocks of the targeted blocks have been programmed with the preload data for the number of blocks.

An example method 6 can include features of any of the preceding example methods and can include the re-programming of the preload data over the programmed preload data in the targeted blocks being performed after a specified delay time has met a target value.

An example method 7 can include features of any of the preceding example methods and can include the programming of preload data and re-programming of the preload data over the programmed preload data in the targeted blocks being performed by first programming reload data for a first block and re-programming the reload data over the preload data in the first block, followed by alternating programming of additional blocks of the targeted blocks between first programming of the additional blocks with preload data for the additional blocks and re-programming the preload data for the additional blocks.

In an example method 8, any of the example methods 1 to 7 may be performed in forming an electronic apparatus further comprising a host processor and a communication bus extending between the host processor and the memory device.

In an example method 9, any of the example methods 1 to 8 may be modified to include operations set forth in any other of example methods 1 to 8.

In an example method 10, any of the example methods 1 to 9 may be implemented at least in part through use of instructions stored as a physical state in one or more machine-readable storage devices.

An example method 11 can include features of any of the preceding example methods 1 to 10 and can include performing functions associated with any features of example memory devices 1 to 10, example memory devices 11 to 21, and example memory systems 1 to 10.

An example method 12 can comprise programming preload data into targeted blocks of a memory device, the memory device having an array arranged as one or more blocks of memory cells; selecting blocks of the targeted blocks for re-programming; and re-programming the preload data for the selected blocks over the programmed preload data in the selected blocks in a same set of memory cells of the selected blocks, without an erase between programming and re-programming the preload data in the selected blocks.

An example method 13 can include features of example method 12 and can include subjecting the memory device to a reflow process after the targeted blocks are programmed with the preload data and each selected block of the targeted blocks has been reprogrammed at least once.

An example method 14 can include features of any of the preceding example methods 12 to 13 and can include selecting the blocks of the targeted blocks for re-programming to include selecting blocks having memory cells with threshold voltage states above a specified state.

An example method 15 can include features of example method 14 and any of the preceding example methods 12 to 13 and can include re-programming the preload data for the selected blocks over the programmed preload data in the selected blocks being performed only on the memory cells having threshold voltage states above the specified state.

An example method 16 can include features of any of the preceding example methods 12 to 15 and can include selecting the blocks of the targeted blocks for re-programming to include selecting blocks having memory cells with a read window budget (RWB) margin below a threshold for a RWB margin.

In an example method 17, any of the example methods 12 to 16 may be performed in forming an electronic apparatus further comprising a host processor and a communication bus extending between the host processor and the memory device.

In an example method 18, any of the example methods 12 to 17 may be modified to include operations set forth in any other of example methods 12 to 17.

In an example method 19, any of the example methods 12 to 18 may be implemented at least in part through use of instructions stored as a physical state in one or more machine-readable storage devices.

An example method 20 can include features of any of the preceding example methods 12 to 19 and can include performing functions associated with any features of example memory devices 1 to 10, example memory devices 11 to 21, and example memory systems 1 to 10.

An example machine-readable storage device 1 storing instructions, that when executed by one or more processors, cause a machine to perform operations, can comprise instructions to perform functions associated with any features of example memory devices 1 to 10, example memory devices 11 to 21, and example memory systems 1 to 10 or perform methods associated with any features of example methods 1 to 20.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array arranged as one or more blocks of memory cells;
a memory controller including processing circuitry to cause the memory device to perform operations including:
programming preload data into targeted blocks of the one or more blocks until the targeted blocks are programmed with the preload data; and
re-programming the preload data over the programmed preload data in the targeted blocks in a same set of memory cells, without an erase between programming and re-programming the preload data.

2. The memory device of claim 1, wherein the operations include erasing the targeted blocks before programming the preload data.

3. The memory device of claim 1, wherein the programming of the preload data is in response to receiving the preload data and a command to program and re-program the preload data in the same set of memory cells without an erase between programming and re-programming the preload data.

4. The memory device of claim 1, wherein the re-programming of the preload data over the programmed preload data is performed more than once without an erase between each of the re-programming the preload data.

5. The memory device of claim 1, wherein the preload data for the one or more targeted blocks partially fills the one or more targeted blocks of the array.

6. A memory device comprising:
an array arranged as blocks of memory cells;
a memory controller including processing circuitry to cause the memory device to perform operations including:
programming preload data into a first block of targeted blocks until the preload data for the first block has been programmed into the first block, the targeted blocks including a first block and additional blocks;
re-programming the preload data over the programmed preload data in a same set of memory cells of the first block of the targeted blocks, without an erase between programming and re-programming the preload data in the first block; and
after re-programming the preload data over the preload data in the first block, alternating programming of additional blocks between first programming of the additional blocks with preload data for the additional blocks and re-programming the preload data for the additional blocks.

7. The memory device of claim 6, wherein the operations include erasing the targeted blocks before programming the preload data for the first block.

8. The memory device of claim 6, wherein the re-programming of the first block starts after a delay time for the re-programming of the first block has met a target value.

9. The memory device of claim 6, wherein the programming of the preload data in the targeted blocks is in response to receiving the preload data and a command to program and re-program the preload data in the same set of memory cells of the targeted blocks without an erase between programming and re-programming the preload data in the same set of memory cells.

10. The memory device of claim 6, wherein the re-programming of the preload data over the programmed preload data in the same set of memory cells is performed more than once without an erase between each of the re-programming the preload data.

11. The memory device of claim 6, wherein the operations include, after re-programming the preload data over the preload data in the first block, programming and re-programming preload data for a second block of the targeted blocks over the preload data in the second block, without an erase between programming and re-programming the preload data for the second block, with the alternating programming of additional blocks beginning after re-programming the preload data over the preload data in the second block.

12. The memory device of claim 6, wherein the operations include, prior to performing the alternating programming of additional blocks:
programming preload data into a second block of the targeted blocks until the first block and the second block are programmed with the preload data for the first block and the second block; and
re-programming the preload data over the programmed preload data in the first block and the second block of the targeted blocks in a same set of memory cells, without an erase between programming and re-programming the preload data in the first block and the second block of the targeted blocks.

13. A method comprising:
programming preload data into targeted blocks of a memory device, the memory device having an array arranged as one or more blocks of memory cells;
re-programming the preload data over the programmed preload data in the targeted blocks in a same set of memory cells, without an erase between programming and re-programming the preload data; and
subjecting the memory device to a reflow process after the targeted blocks are programmed with the preload data and each block of the targeted blocks has been reprogrammed at least once.

14. The method of claim 13, wherein the method includes erasing the targeted blocks before programming the preload data.

15. The method of claim 13, wherein subjecting the memory device to the reflow process includes subjecting the memory device to an infrared reflow process.

16. The method of claim 13, wherein the re-programming of the preload data over the programmed preload data in the targeted blocks is performed after the programming of the preload data in the targeted blocks has been completed.

17. The method of claim 13, wherein the re-programming of the preload data over the programmed preload data in the targeted blocks is performed after a number of blocks of the targeted blocks have been programmed with the preload data for the number of blocks.

18. The method of claim 13, wherein the re-programming of the preload data over the programmed preload data in the targeted blocks is performed after a specified delay time has met a target value.

19. The method of claim 13, wherein the programming of preload data and re-programming of the preload data over the programmed preload data in the targeted blocks is performed by first programming reload data for a first block and re-programming the reload data over the preload data in the first block, followed by alternating programming of additional blocks of the targeted blocks between first programming of the additional blocks with preload data for the additional blocks and re-programming the preload data for the additional blocks.

20. The method of claim 13, wherein the method includes selecting the blocks of the targeted blocks for re-programming having memory cells with threshold voltage states above a specified state.
